(19) United States
(12) Patent Application Publication
(10) Pub. No.: US 2012/0169341 A1
(43) Pub. Date: Jul. 5, 2012

(54) INTEGRATED GAMMA RAY DETECTOR RING AND RF BODY COIL

(75) Inventor: Graeme C. McKinnon, Hartland, WI (US)

(73) Assignee: GENERAL ELECTRIC COMPANY, Schenectady, NY (US)

(21) Appl. No.: 13/035,155

(22) Filed: Feb. 25, 2011

Related U.S. Application Data
(60) Provisional application No. 61/427,958, filed on Dec. 29, 2010.

(51) Int. Cl. G01R 33/00

(52) U.S. Cl. 324/318

(57) ABSTRACT

An integrated gamma ray detector ring and RF coil assembly includes a first RF coil section and a gamma ray detector ring with a first end and a second end. The first end of the gamma ray detector ring is electrically coupled to the first RF coil section. The assembly also includes a second RF coil section that is electrically coupled to the second end of the gamma ray detector ring.

### CROSS REFERENCE TO RELATED APPLICATION

The present application claims the benefit of U.S. Provisional Application Ser. No. 61/427,958, filed Dec. 29, 2010, herein incorporated by reference in its entirety.

### TECHNICAL FIELD

The present invention relates generally to positron emission tomography (PET) and magnetic resonance imaging (MRI), and more specifically, to an integrated PET detector ring and RF body coil for a combined PET/MRI scanner.

### BACKGROUND

PET imaging involves the creation of tomographic images of positron emitting radionuclides in a subject of interest. A radionuclide-labeled pharmaceutical, i.e., a radiopharmaceutical, is administered to an imaging subject. The subject is positioned within a PET imaging system which includes a detector ring and detection electronics. As the radionuclides decay, positively charged particles known as “positrons” are emitted. For commonly used radiopharmaceuticals such as FDG, (i.e., ¹⁸F-fluorodeoxyglucose), these positrons travel only a few millimeters through the tissues of the subject before colliding with an electron, resulting in mutual annihilation. The positron/electron annihilation results in a pair of oppositely-directed gamma rays (gamma photons) that are emitted with approximately 511 keV energy.

It is these gamma rays that are detected by the scintillator components of the detector ring. When struck by a gamma ray, the scintillating material in these components emits light, which is detected by a photodetector component, such as a photodiode or photomultiplier tube. The signals from the photodetectors are processed as incidences of gamma rays. When two gamma rays strike oppositely positioned scintillators at approximately the same time, a coincidence is registered. Data sorting units process the coincidences to determine which are true coincidence events and sort out data representing dead times and single gamma ray detections. The coincidence events are binned and integrated to form frames of PET data which may be reconstructed as images depicting the distribution of the radionuclide-labeled pharmaceutical in the subject.

MRI is a medical imaging modality that can create pictures of the inside of a human body without using x-rays or other ionizing radiation. MRI uses a powerful magnet to create a strong, uniform, static magnetic field (i.e., the “main magnetic field”). When a human body, or part of a human body, is placed in the main magnetic field, the nuclear spins that are associated with the hydrogen nuclei in tissue water become polarized. This means that the magnetic moments that are associated with these spins become preferentially aligned along the direction of the main magnetic field, resulting in a small net tissue magnetization along that axis (the “z axis”, by convention). An MRI system also comprises components called gradient coils that produce smaller amplitude, spatially varying magnetic fields when current is applied to them. Typically, gradient coils are designed to produce a magnetic field component that is aligned along the z axis and that varies linearly in amplitude with position along one of the x, y or z axes. The effect of a gradient coil is to create a small ramp on the magnetic field strength and concomitantly on the resonant frequency of the nuclear spins, along a single axis. Three gradient coils with orthogonal axes are used to “spatially encode” the MR signal by creating a signature resonance frequency at each location in the body. Radio frequency (RF) coils are used to create pulses of RF energy at or near the resonance frequency of the hydrogen nuclei. These coils are used to add energy to the nuclear spin system in a controlled fashion. As the nuclear spins then relax back to their rest energy state, they give up energy in the form of an RF signal. This signal is detected by the MRI system, and combined with multiple additional such signals may be used to reconstruct an MR image using a computer and known algorithms.

Combining PET and MRI in a single scanner presents difficult technical challenges. An MRI scanner is typically designed to have the gradient coils, RF coils, shielding and cooling systems packed as close together as possible. Prior combined systems have located the PET detector components outside of an RF shield and within the gradient coil and magnet space of the MR magnet assembly. For example, prior solutions have included splitting the gradient coil to make space for a ring of PET detectors, splitting the gradient coil and magnet to make space for a ring of PET detectors or within the gradient coil and magnet space, separating the crystal and detector electronics used in the PET detector with fiber optic cables. However, these arrangements can take up significant radial space. In addition, the PET and MRI systems must not interfere with one another electrically. Accordingly, it would be desirable to provide a solution for integrating a PET detector, for example a ring of PET detectors, into a MRI magnet assembly by integrating the PET detector with the RF body coil of the magnet assembly.

### BRIEF DESCRIPTION OF THE INVENTION

In accordance with an embodiment, an integrated gamma ray detector ring and RF coil assembly includes a first RF coil section, a gamma ray detector ring having a first end and a second end, the first end electrically coupled to the first RF coil section and a second RF coil section electrically coupled to the second end of the gamma ray detector ring.

In accordance with another embodiment, a combined PET/MRI system includes a superconducting magnet, a gradient coil assembly disposed within an inner diameter of the superconducting magnet and an integrated gamma ray detector ring and RF coil assembly disposed within an inner diameter of the gradient coil assembly. The integrated gamma ray detector ring and RF coil assembly comprising a first RF coil section, a gamma ray detector ring having a first end and a second end, the first end electrically coupled to the first RF coil section and a second RF coil section electrically coupled to the second end of the gamma ray detector ring.

### BRIEF DESCRIPTION OF THE DRAWINGS

Embodiments are illustrated by way of example and not limitation in the accompanying drawings, in which like reference numerals indicate corresponding, analogous or similar elements, and in which:

FIG. 1 is a schematic block diagram of a combined PET/MRI system in accordance with an embodiment;

FIG. 2 is a schematic diagram of an integrated gamma ray detector ring and an RF body coil assembly in accordance with an embodiment;

FIG. 3 shows an exemplary gamma ray detector ring in accordance with an embodiment;

FIG. 4 shows the gamma ray detector ring of FIG. 2 wrapped in an RF shield in accordance with an embodiment;

FIG. 5 is a schematic diagram of an integrated gamma ray detector ring and RF body coil assembly with an outer RF shield in accordance with an embodiment; and

FIG. 6 is a schematic diagram of a magnet assembly with an integrated gamma ray detector ring and RF body coil assembly in accordance with an alternative embodiment.

### DETAILED DESCRIPTION

In the following detailed description, numerous specific details are set forth in order to provide a thorough understanding of embodiments. However it will be understood by those of ordinary skill in the art that the embodiments may be practiced without these specific details. In other instances, well-known methods, procedures, components and circuits have not been described in detail an as not to obscure the embodiments.

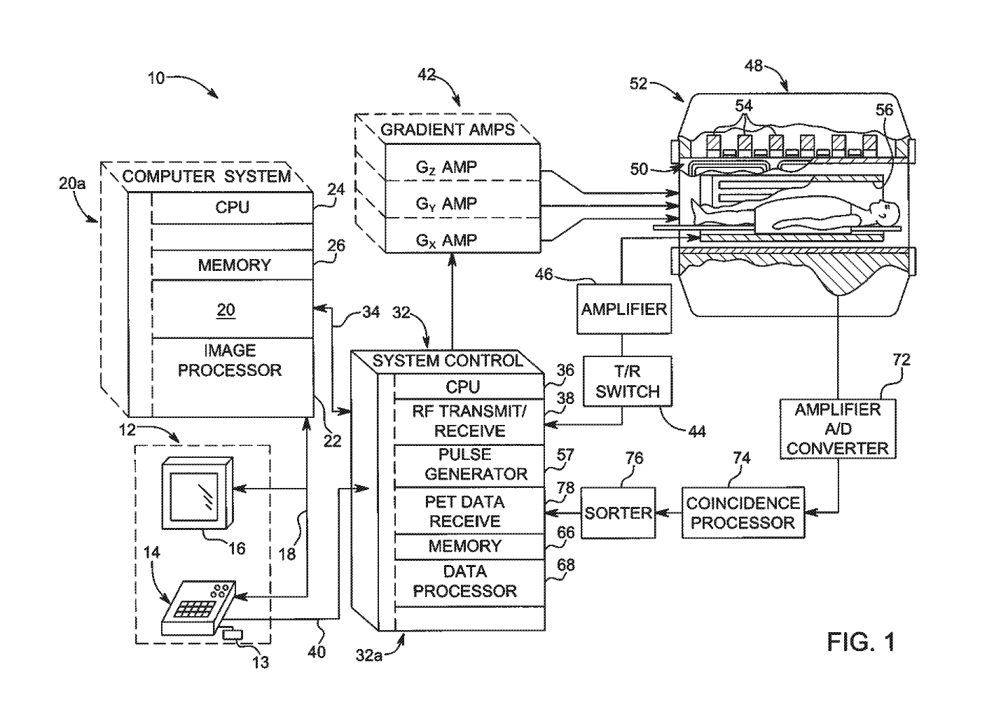

Referring to FIG. 1, the main components of an exemplary combined PET/MRI system 10 that may incorporate embodiments of the present invention are shown. The operation of the system may be controlled from an operator console 12 which includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through electrical and/or data connections, for example, such as are provided by using a backplane 20a. Data connections may be direct wired links or may be fiber optic connections or wireless communications links or the like. The modules include an image processor module 22, a CPU module 24 and a memory module 26, which may include a frame buffer for storing image data arrays. In an alternative embodiment, the image processor module 22 may be replaced by image processing functionality on the CPU module 24. The computer system 20 may also be connected to permanent or back-up memory storage, a network, or may communicate with a separate system control 32 through a link 34. The input device 13 can include a mouse, joystick, keyboard, track ball, touch activated screen, light wand, voice control, or any similar or equivalent input device, and may be used for interactive geometry prescription.

The system control 32 includes a set of modules in communication with each other via electrical and/or data connections 32a. Data connections 32a may be direct wired links or may be fiber optic connections or wireless communication links or the like. System control 32 is connected to the operator console 12 through a communications link 40. It is through link 40 that the system control 32 receives commands from the operator to indicate the scan sequence or sequences that are to be performed. The modules of system control computer 32 include a CPU module 36 and a pulse generator module 57 that connects to the operator console 12 through a communications link 40. For MR data acquisition, an RF transmit/receive module 38 commands the scanner 48 to carry out the desired scan sequence, by sending instructions, commands, and/or requests describing the timing, strength and shape of the RF pulses and pulse sequences to be produced, to correspond to the timing and length of the data acquisition window. In this regard, a transmit/receive switch 44 controls the flow of data via amplifier 46 to scanner 48 from RF transmit module 38 and from scanner 48 to RF receive module 38. The system control 32 also connects to a set of gradient amplifiers 42 to indicate the timing and shape of the gradient pulses that are produced during the scan.

The gradient waveform instructions produced by system control 32 are sent to the gradient amplifier system 42 having Gx, Gy, and Gz amplifiers, Gradient amplifiers 42 may be external of scanner 48 or system control 32, or may be integrated therein. Each gradient amplifier excites a corresponding physical gradient coil in a gradient coil assembly generally designated 50 to produce the magnetic field gradients used for spatially encoding acquired signals. The gradient coil assembly 50 forms part of a magnet assembly 52 which also includes a polarizing magnet 54 and an RF coil assembly 56. Alternatively, the gradient coils of gradient coil assembly 50 may be independent of magnet assembly 52. RF coil assembly 56 may include a whole-body RF transmit coil as shown, surface or parallel imaging coils (not shown), or a combination of both. The coils of the RF coil assembly 56 may be configured for both transmitting and receiving, or for transmit-only or receive-only. A pulse generator 57 may be integrated into system control 32 as shown or may be integrated into the scanner equipment 48 and produces pulse sequences or pulse sequence signals for the gradient amplifiers 42 and/or the RF coil assembly 56. Alternatively, RF coil assembly 56 may be replaced or augmented with surface and/or phased array receive coils. The MR signals resulting from the excitation pulses, emitted by the excited nuclei in the patient, may be sensed by the whole body coil or by separate receive coils, such as phased array coils or surface coils, and are then sent to the RF transmit/receive module 38 via T/R switch 44. The MR signals are demodulated, filtered, and digitized in the data processing section 68 of the system control 32.

An MRI scan is complete when one or more sets of raw k-space data has been acquired in the data processor 68. This raw k-space data is reconstructed in data processor 68 which operates to transform the data (through Fourier transformation or another technique) into image data. This image data is conveyed through the link 34 to the computer system 20 where it is stored in memory 26. Alternatively, in some systems, computer system 20 may assume the image reconstruction or other functions of data processor 68. In response to commands received from the operator console 12, the image data stored in memory 26 may be archived in long term storage or may be further processed by the image processor 22 and conveyed to the operator console 12 and presented on the display 16.

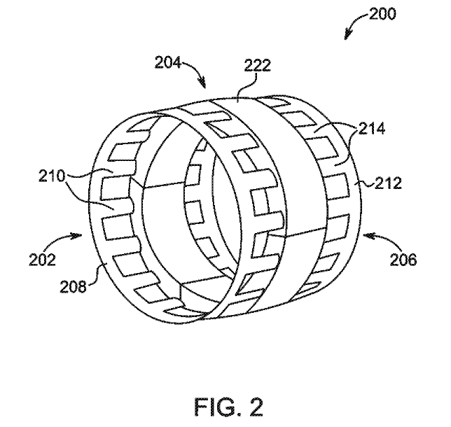

In the combined PET/MRI system 10, scanner 48 also contains a gamma ray detector or detectors (not shown) (e.g., a ring of gamma ray detectors) incorporated into the RF coil assembly as described below with respect to FIGS. 2-6. The gamma ray detector is configured to detect gamma rays from positron annihilations and may include a plurality of scintillators and photodetectors arranged circumferentially about a gantry (i.e., a ring of gamma ray detectors or a detector ring).

Gamma ray incidences are detected and transformed into electrical signals by the gamma ray detector. The electrical signals are conditioned by a series of front-end electronics 72. These conditioning circuits 72 may include various amplifiers, filters, and analog-to-digital converters. The digital signals output by the front end electronics 72 are then processed by a coincidence processor 74 to match gamma ray detections as potential coincidence events. When two gamma rays strike detectors approximately opposite one another, it is possible, absent the interactions of random noise and single gamma ray detections, that a positron annihilation took place somewhere along the line between the detectors. Thus, the coincidences determined by the coincidence processor 74 are sorted into true coincidence events and are ultimately integrated by a data sorter 76. The coincidence event data, or PET data, from the data sorter 76 is received by the system control 32 at a PET data receive port 78 and stored in memory 66 for subsequent processing by the processor 68. PET images may then be reconstructed by the image processor 22 and may be combined with MR images to produce hybrid structural and metabolic or functional images. The conditioning circuits 72, coincidence processor 74 and sorter 76 may each be external of the scanner 48 or the control system 32 or may be integrated therein.

FIG. 2 is a schematic diagram of an integrated gamma ray detector ring and RF coil assembly in accordance with an embodiment. The integrated gamma ray detector ring and RF coil assembly 200 may be used in a combined PET/MRI scanner (such as scanner 48 shown in FIG. 1). Assembly 200 includes a first RF coil section 202, a gamma ray detector ring 204 and a second RF coil section 206. Various other elements such as supports, suspension members, brackets, etc. are omitted from FIG. 2 for clarity. Assembly 200 is cylindrical and annular in shape.

First RF coil section 202 includes a first end ring 208 and a first plurality of rungs 210 and the second RF coil section 206 includes a second end ring 212 and a second plurality of rungs 214. The first RF coil section 202 and the second RF coil section 206 also include capacitors (not shown), for example, series capacitors, to achieve the appropriate resonant operation as known in the art. In an embodiment, the first RF coil section 202 and the second RE coil section 206 are in a birdcage coil configuration, for example, a high pass, a low pass or a band pass coil. In another embodiment, the first RF coil section 202 and the second RF coil section 206 are in a TEM coil configuration. The first and second RF coil sections 202, 206 may be used to apply RF pulses to a subject or patient and to receive MR data from the subject.

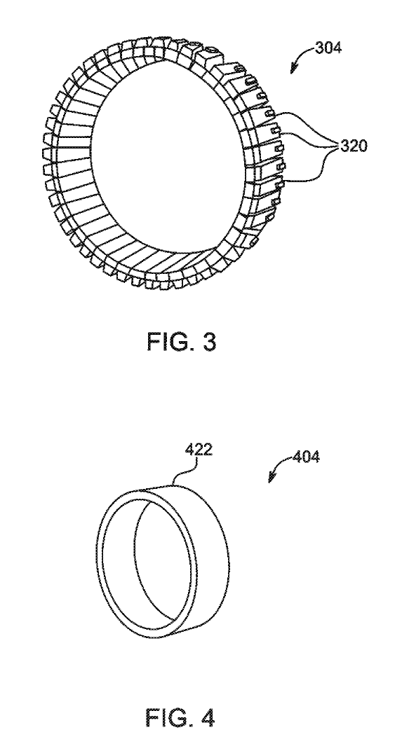

Gamma ray detector ring 204 is placed between and connected to the first RF coil section 202 and the second RF coil section 206. In a preferred embodiment, gamma ray detector ring 204 consists of a plurality of gamma ray detectors that are surrounded by a RF shield. FIG. 3 shows an exemplary gamma ray detector ring in accordance with an embodiment. Detector ring 304 includes a plurality of gamma ray detectors 320 distributed circumferentially in a ring. Each gamma ray detector 320 includes a scintillator component and a photo detector component as well as other electronics as known in the art. The scintillator component of a gamma ray detector 320 includes scintillator material that creates a burst of light when a gamma ray is received. Scintillator materials that may be used include, for example, bismuth germinate (BGO), sodium iodide (NaI), gadolinium oxyorthosilicate (GS)), lutetium-ortho-silicate (LSO) or other compounds with similar light-emitting properties. The photo detector component detects the burst of light emitted from the scintillator component and converts it into electrical currents that may be amplified by an amplifier (for example, an amplifier included in front-end electronics 72, shown in FIG. 1). In a preferred embodiment, the photo detector component is a solid-state photo detector, such as a solid-state photomultiplier (SSPM).

As mentioned above, to integrate the gamma ray detector ring 304 into the RF coil, the gamma ray detector ring is encased in an RF shield. FIG. 4 shows the gamma ray detector ring wrapped in an RF shield in accordance with an embodiment. The gamma ray detectors of the gamma ray detector ring 404 are surrounded or covered by an RF shield 422. In a preferred embodiment, the RF shield is placed completely around the detector ring and has a rectangular cross-sectioned toroidal structure. RF shield 422 may be fabricated from any suitable conducting material, for example, sheet copper, circuit boards with conducting copper traces, copper mesh, stainless steel mesh, other conducting wire mesh, etc. RF shield 422 is configured to be transparent to the magnetic fields generated by the gradient coils and also transparent to the gamma photons impinging on the entrance to the gamma ray detectors.

Returning to FIG. 2, as mentioned, the RF shielded gamma ray detector ring 204 is placed between the first RF coil section 202 and the second RF coil section 206. A first end of rungs 210 is connected to the first end ring 208 and a second end of rings 210 is electrically connected to the RF shield 222 surrounding the gamma ray detector ring 204. A first end of rungs 214 is connected to the second end ring 212 and a second end of rungs 214 is electrically connected to the RF shield 222 surrounding the gamma ray detector ring 204. Accordingly, in the integrated assembly 200 the RF coil section 202, 206 and RF shielded gamma ray detector ring 204 are merged and electrically combined. Rungs 210 and 214 may be connected to the RF shield 222 using known methods such as, for example, soldering or braising.

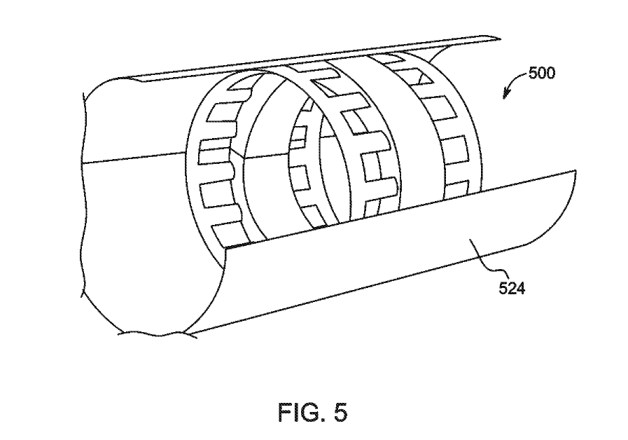

To complete an RF environment for the integrated assembly 200 in a combined PET.MRI system, a cylindrical RF shield is disposed around the integrated assembly 200. FIG. 5 is a schematic diagram of an integrated gamma ray detector ring and RF coil assembly in accordance with an embodiment. RF shield 524 is cylindrical and annular in shape. In FIG. 5, one quadrant of the RF shield 524 is cut away for clarity and ease of understanding of how the structures are positioned. RF shield 524 is disposed around the integrated gamma ray detector ring and RF coil assembly 500 and circumferentially surrounds the integrated assembly 500. In the embodiment, shown, the length of RF shield 524 is greater than the length of the integrated assembly 500. RF shield 524 may be fabricated from any suitable conducting material, for example, sheet copper, circuit boards with conducting copper traces, copper mesh, stainless steel mesh, other conducting wire mesh, etc. In one embodiment, the RF shield 524 is electrically isolated (i.e., not in contact with) from the integrated assembly 500. In another embodiment, the RF shield 524 is connected to integrated assembly 500. If the RF shield and integrated assembly are touching, preferably the RF coils sections of the integrated assembly 200 (shown in FIG. 2) are driven from both ends of the assembly.

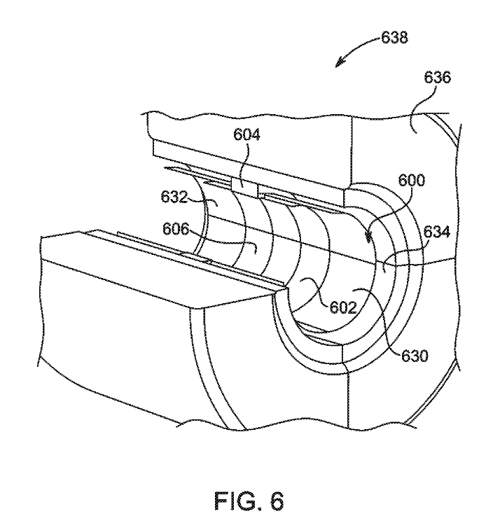

In an alternative embodiment, the RF shield 524 may also be split, similar to the RF coil. FIG. 6 is a schematic diagram of a magnet assembly with an integrated gamma ray detector ring and RF coil assembly in accordance with an embodiment. In FIG. 6, a cylindrical and annular shaped magnet assembly 638 is shown where one quadrant of the magnet assembly 638 is cut away for clarity and ease of understanding of how the structures are positioned. Magnet assembly 638 includes a gradient coil assembly 634 that is mounted inside a superconducting magnet 636 and circumferentially surrounded by magnet 636. An RF shield 624 and an integrated gamma ray detector ring and RF coil assembly 600 are mounted inside the gradient coil assembly 634 and are circumferentially surrounded by the gradient coil assembly 634. RF shield 624 consists of a first RF shield section 630 and a second RF shield section 632. The RF shielded gamma ray detector ring 604 is placed between and connected to the first RF shield section 630 and the second RF shield section 632. The gamma ray detector ring 604 is also placed between and connected to the first RF coil section 602 and the second RF coil section 606 as described above. An end of the first RF shield section 630 is electrically connected to the RF shielded gamma ray detector ring 604 and an end of the second RF shield section 632 is electrically connected to the RF shielded gamma ray detector ting 604.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. The order and sequence of any process or method steps may be varied or re-sequenced according to alternative embodiments.

Many other changes and modifications may be made to the present invention without departing from the spirit thereof. The scope of these and other changes will become apparent from the appended claims.

What is claimed is:

1. An integrated gamma ray detector ring and RF coil assembly comprising:
a first RF coil section;
a gamma ray detector ring having a first end and a second end, the first end electrically coupled to the first RF coil section; and
a second RF coil section electrically coupled to the second end of the gamma ray detector ring.

2. An assembly according to claim 1, further comprising an RF shield disposed around the first RF coil section, the gamma ray detector ring and the second RF coil section.

3. An assembly according to claim 1, wherein the first RF coil section comprises a first end ring and a first plurality of rungs.

4. An assembly according to claim 1, wherein the second end ring section comprises a second end ring and a second plurality of rungs.

5. An assembly according to claim 1, wherein the gamma ray detector ring comprises a plurality of gamma ray detectors and an RF shield disposed around the plurality of gamma ray detectors.

6. An assembly according to claim 5, wherein the first RF coil section comprises a first end ring and a first plurality of rungs and the first end ring is coupled to a first end of the first plurality of rungs and a second end of the first plurality of rungs is coupled to the first end of the gamma ray detector ring.

7. An assembly according to claim 6, wherein the second end of the first plurality of rungs is electrically connected to the RF shield disposed around the plurality of gamma ray detectors.

8. An assembly according to claim 5, wherein the second RF coil section comprises a second end ring and a second plurality of rungs and the second end ring is coupled to a first end of the second plurality of rungs and a second end of the second plurality of rungs is coupled to the second end of the gamma ray detector ring.

9. An assembly according to claim 8, wherein the second end of the second plurality of rungs is electrically connected to the RF shield disposed around the plurality of gamma ray detectors.

10. An assembly according to claim 5, wherein each gamma ray detector in the plurality of gamma ray detectors is a solid state photomultiplier.

11. A combined PET/MRI system comprising:
a superconducting magnet;
a gradient coil assembly disposed within an inner diameter of the superconducting magnet; and
an integrated gamma ray detector ring and RF coil assembly disposed within an inner diameter of the gradient coil assembly, the integrated gamma ray detector ring and RF coil assembly comprising:
a first RF coil section;
a gamma ray detector ring having a first end and a second end, the first end electrically coupled to the first RF coil section; and
a second RF coil section electrically coupled to the second end of the gamma ray detector ring.

12. A combined PET/MRI system according to claim 11, further comprising an RF shield disposed around the first RF coil section, the gamma ray detector ring and the second RF coil section.

13. A combined PET/MRI system according to claim 11, wherein the first RF coil section comprises a first end ring and a first plurality of rungs.

14. A combined PET/MRI system according to claim 11, wherein the second end ring section comprises a second end ring and a second plurality of rungs.

15. A combined PET/MRI system according to claim 11, wherein the gamma ray detector ring comprises a plurality of gamma ray detectors and an RF shield disposed around the plurality of gamma ray detectors.

16. A combined PET/MRI system according to claim 15, wherein the first RF coil section comprises a first end ring and a first plurality of rungs and the first end ring is coupled to a first end of the first plurality of rungs and a second end of the first plurality of rungs is coupled to the first end of the gamma ray detector ring.

17. A combined PET/MRI system according to claim 16, wherein the second end of the first plurality of rungs is electrically connected to the RF shield disposed around the plurality of gamma ray detectors.

18. A combined PET/MRI system according to claim 15, wherein the second RF coil section comprises a second end ring and a second plurality of rungs and the second end ring is coupled to a first end of the second plurality of rungs and a second end of the second plurality of rungs is coupled to the second end of the gamma ray detector ring.

19. A combined PET/MRI system according to claim 18, wherein the second end of the second plurality of rungs is electrically connected to the RF shield disposed around the plurality of gamma ray detectors.

20. A combined PET/MRI system according to claim 15, wherein each gamma ray detector in the plurality of gamma ray detectors is a solid state photomultiplier.
